(19) United States
(12) Patent Application Publication
(10) Pub. No.: US 2023/0282805 A1
(43) Pub. Date: Sep. 7, 2023

(54) REFERENCE ELECTRODE FOR ON-BOARD BATTERY CELL DIAGNOSTICS AND METHOD OF REFERENCE ELECTRODE FABRICATION

(71) Applicant: GM GLOBAL TECHNOLOGY OPERATIONS LLC, Detroit, MI (US)

(72) Inventors: Gayatri V. Dadheech, Bloomfield Hills, MI (US); Mark W. Verbrugge, Troy, MI (US); Brian J. Koch, Berkley, MI (US); Jing Gao, Rochester, MI (US); Alok Warey, Novi, MI (US)

(73) Assignee: GM GLOBAL TECHNOLOGY OPERATIONS LLC, Detroit, MI (US)

(21) Appl. No.: 17/685,700

(22) Filed: Mar. 3, 2022

(51) Int. Cl. H01M 4/134; H01M 10/48; G01R 31/382; H01M 10/0525; C23C 18/54; H01M 4/04

(52) U.S. Cl. CPC H01M 4/134; C23C 18/54; G01R 31/382; H01M 4/0438; H01M 10/0525; H01M 10/48

(57) ABSTRACT

A reference electrode assembly for an electrochemical cell includes a separator constructed from an electrically-insulating porous material. The reference electrode assembly also includes a current collector having a sputtered electrically-conducting porous layer arranged directly on the separator and a sputtered lithium iron phosphate (LFP) layer arranged directly on the electrically-conducting porous layer. The reference electrode assembly additionally includes an electrical contact connected to the current collector. A method using successive vacuum deposition of individual layers onto the separator is employed in fabricating the reference electrode assembly.

### INTRODUCTION

The present disclosure relates to a reference electrode for on-board battery cell diagnostics and a method of fabricating the same.

High-energy density, electrochemical cells, such as lithium-ion batteries may be used in a variety of consumer products and vehicles, such as Hybrid Electric Vehicles (HEVs) and Electric Vehicles (EVs). Typical lithium-ion, lithium sulfur, and lithium-lithium symmetrical batteries include a first electrode, a second electrode, an electrolyte material, and a separator. One electrode serves as a positive electrode or cathode and another serves as a negative electrode or anode. A stack of battery cells may be electrically connected to increase overall output.

Rechargeable lithium-ion batteries operate by reversibly passing lithium-ions back and forth between the negative electrode and the positive electrode. A separator and an electrolyte are disposed between the negative and positive electrodes. The electrolyte is suitable for conducting lithium-ions and may be in solid (e.g., solid state diffusion) or liquid form. Lithium-ions move from a cathode (positive electrode) to an anode (negative electrode) during charging of the battery, and in the opposite direction when discharging the battery. It may be desirable to perform electrochemical analysis on batteries or certain components of batteries, such as the cathode and the anode.

For example, electrochemical analysis may produce calibrations for control systems in electric vehicles pertaining to fast charge, lithium plating, state of charge, and power estimation. The electrodes may be analyzed by providing a reference electrode in an electrochemical cell having positive and negative electrodes. The reference electrode enables monitoring of individual positive and negative electrode potentials as the cell is being cycled. Potentials may be monitored in a lab setting or during real-time use of a system including the electrochemical cell. For example, potentials may be detected during operation of a vehicle, as part of regular vehicle diagnostics. Detected potentials may be used in vehicle control algorithms to improve cell performance, such as by raising anode potential to decrease lithium plating.

A properly operating reference electrode is required to permit accurate and reproducible measurements for analysis of an electrochemical cell. Therefore, a reference electrode should have stable and reproducible potential. Reference electrodes used are preferably reversible type electrodes. In a reversible electrode a small cathodic current produces the reduction reaction, while a small anodic current produces the oxidation reaction. Generally, the three main requirements for a satisfactory reference electrode, are reversibility (non-polarizability), reproducibility, and stability.

### SUMMARY

A reference electrode assembly for an electrochemical cell includes a separator constructed from an electrically-insulating porous material. The reference electrode assembly also includes a current collector having a sputtered electrically-conducting porous layer arranged directly on the separator and a sputtered lithium iron phosphate (LFP) layer arranged directly on the electrically-conducting porous layer. The reference electrode assembly additionally includes an electrical contact connected to the current collector.

The electrical contact may include either a gold/graphite or a silver epoxy tab.

The separator may be either doped or coated with a ceramic material to minimize a likelihood of an electrical short circuit.

The electrically-conducting porous layer may include an aluminum layer having a thickness in a 50-500 nm range and arranged directly on the separator.

The electrically-conducting porous layer having the aluminum layer may additionally include a carbon layer having a thickness in a 5-50 nm range and arranged directly on the aluminum layer, such that the aluminum layer is sandwiched between the separator and the carbon layer.

The electrically-conducting porous layer may include a graphite-carbon layer having a thickness in a 50-500 nm range and arranged directly on the separator.

The electrically-conducting porous layer may include a nickel layer having a thickness in a 50-500 nm range and arranged directly on the separator.

The electrically-conducting porous layer may include a Tin layer having a thickness in a 50-500 nm range and arranged directly on the separator.

The LFP layer may have a thickness in a 70-500 nm range.

A particular method using successive vacuum deposition of individual layers onto the separator is employed in fabricating the reference electrode assembly.

Specifically, the method may include setting up the separator in the vacuum chamber with arranging the separator on a movable fixture. In the subject embodiment, the method may also include applying the current collector onto the separator with bombarding a stationary current collector target and a stationary LFP target to vacuum deposit the respective layers onto the current collector while transporting the movable fixture.

Alternatively, the method may include setting up in the vacuum chamber the separator with arranging the separator on a stationary fixture. In the subject embodiment, the method may also include setting up a current collector target and an LFP target on a movable fixture, such as a rotatable turret, and sequentially bombarding the respective current collector target and the LFP target while shifting the movable fixture to vacuum deposit the respective layers onto the current collector.

The above features and advantages, and other features and advantages of the present disclosure, will be readily apparent from the following detailed description of the embodiment(s) and best mode(s) for carrying out the described disclosure when taken in connection with the accompanying drawings and appended claims.

### BRIEF DESCRIPTION OF THE DRAWINGS

FIG. 1 is a schematic view of an electrical energy storage cell powering a load, the energy storage cell being shown as a lithium-ion (Li-Ion) battery having a lithium anode, a suitable cathode, and a reference electrode assembly having an electrically-conducting porous layer and an LFP layer, according to the disclosure.

FIG. 2 is a schematic view of an embodiment of the reference electrode assembly shown in FIG. 1.

FIG. 3 is a schematic view of another embodiment of the reference electrode assembly shown in FIG. 1.

FIG. 4 illustrates a method of fabricating a reference electrode assembly, shown in FIGS. 1-3, for an electrochemical cell, according to the disclosure.

FIG. 5 is a schematic illustration of a current collector being applied onto a reference electrode separator via shifting a movable fixture with the reference electrode separator along with sequentially bombarding stationary current collector and stationary LFP targets in a sputtering chamber to vacuum deposit the electrically-conducting porous layer and the LFP layer shown in FIGS. 1-3, onto the current collector according to the disclosure.

FIG. 6 is a schematic illustration of a current collector being applied onto a reference electrode separator via shifting a movable fixture with indexed current collector and LFP targets and sequentially bombarding the targets in a sputtering chamber to vacuum deposit the electrically-conducting porous layer and the LFP layer, according to the disclosure.

### DETAILED DESCRIPTION

Those having ordinary skill in the art will recognize that terms such as “above,” “below,” “upward,” “downward,” “top,” “bottom,”, “left”, “right”, etc., are used descriptively for the figures, and do not represent limitations on the scope of the disclosure, as defined by the appended claims. Furthermore, the teachings may be described herein in terms of functional and/or logical block components and/or various processing steps. It should be realized that such block components may be comprised of a number of hardware, software, and/or firmware components configured to perform the specified functions.

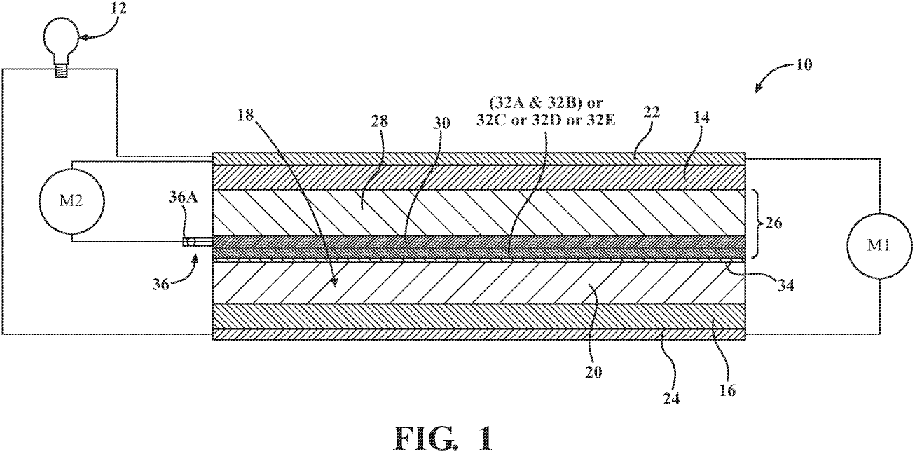

Referring to FIG. 1, an electrochemical storage cell 10 powering a load 12 is depicted. The electrochemical storage cell 10 is specifically shown as a lithium-ion (Li-Ion) pouch battery cell having an anode (negative electrode) 14, a cathode (positive electrode) 16, and a non-aqueous electrolyte 18 surrounding the anode, cathode, and flowing through a separator diaphragm or first separator 20. The anode 14 may be constructed from lithium, graphite, silicon, silicon oxide and various other suitable material. While the cathode 16 is frequently constructed from sulfur, other Li ion battery cathode material, such as lithium manganese oxide, lithium iron phosphate, lithium nickel/manganese/cobalt oxide, or a variety of other suitable materials, may also be used. Li-Ion batteries are rechargeable electrochemical batteries notable for their high specific energy and low self-discharge. The Li-Ion batteries may be used to power such diverse items as toys, consumer electronics, and motor vehicles. The subject vehicle may include, but not be limited to, a commercial vehicle, industrial vehicle, passenger vehicle, aircraft, watercraft, train or the like. It is also contemplated that the vehicle may be a mobile platform, such as an airplane, all-terrain vehicle (ATV), boat, personal movement apparatus, robot and the like to accomplish the purposes of the present disclosure.

In Li-Ion batteries, lithium ions move from the anode 14 through the electrolyte 18 to the cathode 16 during discharge, and back when charging. Li-Ion batteries use a lithium compound as the material at the positive electrode and typically graphite at the negative electrode. Generally, the reactants in the electrochemical reactions in a Li-Ion cell 10 are materials of anode and cathode, both of which are compounds that may host lithium atoms. During discharge, an oxidation half-reaction at the anode 14 produces positively charged lithium ions and negatively charged electrons. The oxidation half-reaction may also produce uncharged material that remains at the anode 14. Lithium ions move through the electrolyte 18, electrons move through an external circuit (including a connection to the electrical load 12 or to a charging device), and then they recombine at the cathode (together with the cathode material) in a reduction half-reaction. The electrolyte 18 and the external circuit provide conductive media for lithium ions and electrons, respectively, but do not partake in the electrochemical reaction.

Generally, during discharge of an electrochemical battery cell, electrons flow from the anode 14 toward the cathode 16 through the external circuit. The reactions during discharge lower the chemical potential of the cell, so discharging transfers energy from the cell to wherever the electric current dissipates its energy, mostly in the external circuit. During charging, the described reactions and transports go in the opposite direction: electrons move from the positive electrode to the negative electrode through the external circuit. To charge the cell, the external circuit has to provide electric energy. This energy is then stored (with some loss) as chemical energy in the cell. In a Li-Ion cell, both the anode 14 and cathode 16 allow lithium ions to move in and out of their structures via a process called insertion (intercalation) or extraction (deintercalation), respectively. Typically, the anode 14 and the cathode 16 are associated with respective electrically conductive current collectors - an anode current collector 22 and a cathode current collector 24. Each current collector 22, 24 may include metal in the form of metal foil, a metal grid or screen, or expanded metal having suitable thickness to accommodate an increased amount of electrode material. Current collector materials may, for example, include copper, nickel, aluminum, and various electrically conductive alloys.

It may be desirable to perform electrochemical analysis on the anode 14 and cathode 16 electrodes to produce calibrations for control systems employing the electrochemical storage cell 10, such as in hybrid electric and electric vehicles, for example pertaining to fast charge, lithium plating, state of charge, and power estimation. The anode 14 and cathode 16 electrodes may be analyzed by providing a reference electrode assembly 26 (shown in FIGS. 1-3) in the Li-Ion cell 10. The reference electrode assembly 26 may enable monitoring of individual positive and negative electrode potentials as the Li-Ion cell 10 is being cycled and be used to provide cell overcharge protection. With a reference electrode, potential of the cathode electrode 16 may be controlled directly and optimized over the life of the Li-Ion cell 10. In general, effectiveness of a reference electrode in providing stable and reproducible potential and non-polarizability via reversible reactions is directly related to the electrode’s performance. The Li-Ion cell 10 may include an antenna (not shown) for communicating cell data, including voltage data from the reference electrode assembly 26, to a control system, such as an electronic control unit (ECU) of an automotive vehicle.

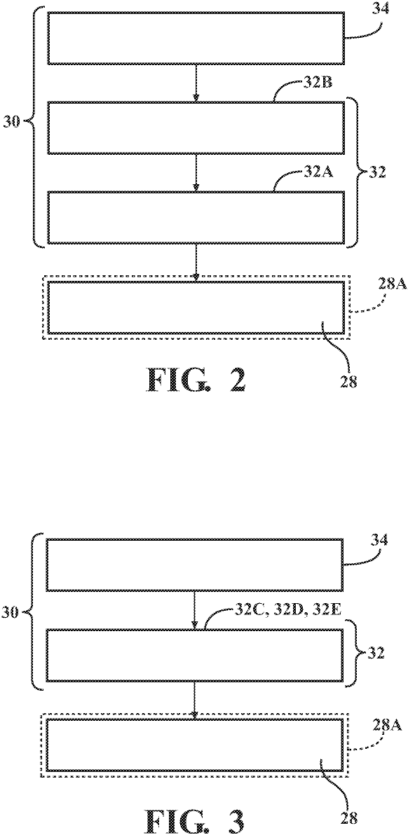

The reference electrode assembly 26 is disposed between the anode 14 and the separator diaphragm 20. The reference electrode assembly 26 includes a second separator 28. The second separator 28 is constructed from an electrically-insulating porous material providing increased surface area, compared to a non-porous material, for faster charging. The second separator 28 may be constructed from a polymer or a mixture of polymeric materials, such as polypropylene or polyethylene, or aramid fibers. Additionally, the second separator 28 may be either doped or coated with an insulating ceramic material 28A (shown in FIGS. 2-3) to minimize the likelihood of an electrical short circuit during operation of the Li-Ion cell 10. For example, the insulating ceramic material 28A may be alumina or silica.

The reference electrode assembly 26 also includes a reference current collector 30. The reference current collector 30 has an electrically-conducting porous layer 32 arranged on the second separator 28. Specifically, the reference current collector 30 is sputtered, in a vacuum chamber, directly onto the second separator 28. The electrically-conducting porous layer 32 may include an aluminum layer 32A arranged on the second separator 28 and may additionally include a carbon layer 32B arranged on the aluminum layer 32A (shown in FIG. 2). The aluminum layer 32A is intended to be vacuum deposited or sputtered directly onto the second separator 28, while the carbon layer 32B is intended to be sputtered directly onto the aluminum layer 32A. In the embodiment having both the aluminum layer 32A and the carbon layer 32B, the aluminum layer is intended to be sandwiched between the separator 28 and the carbon layer. The aluminum layer may have thickness in a 50-500 nm range, and more specifically a thickness of 200 nm. The carbon layer 32B is employed for maintaining a low increase in contact resistance, and may have thickness in a 5-50 nm range, and more specifically a thickness of 20 nm.

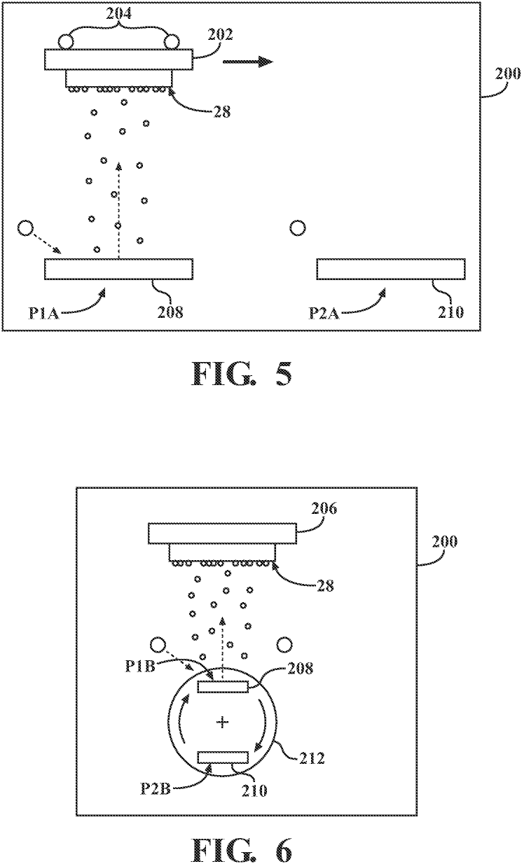

In a separate embodiment shown in FIG. 3, the electrically-conducting porous layer 32 may include a graphite-carbon layer 32C arranged directly on the separator 28. The graphite-carbon layer 32C may be sputtered with a thickness in a 50-500 nm range, and more specifically having a thickness of 300 nm. In another embodiment shown in FIG. 5, the electrically-conducting porous layer 32 may include a nickel (Ni) layer 32D arranged directly on the separator 28. The nickel layer 32D may be sputtered with a thickness in a 50-500 nm range, and more specifically having a thickness of 250 nm. In a further embodiment shown in FIG. 3, the electrically-conducting porous layer 32 may include a Tin (Sn) layer 32E arranged directly on the separator 28. The Tin layer 32E may be sputtered with a thickness in a 50-500 nm range, and more specifically having a thickness of 200 nm.

The reference electrode assembly 26 additionally includes a sputtered lithium iron phosphate (LFP) layer 34 arranged directly on the electrically-conducting porous layer 32 (shown in FIGS. 1-3). The LFP layer 34 provides stable and reproducible potential across a wide range of lithium content in the reference electrode assembly 26. The LFP layer 34 may have a thickness in a 70-500 nm range. Furthermore, the reference electrode assembly 26 includes an electrical contact 36 connected to the current collector 30. The electrical contact 36 may include a tab 36A formed either from a gold/graphite or silver epoxy. Overall, the progressively sputtered constituent layers - the current collector 30, the electrically-conducting porous layer 32, and the LFP layer 34 - onto the second separator 28 interlock and result in a reference electrode assembly 26 formed as a unitary, i.e., one-piece, component. Furthermore, materials of the sputtered layers 32, 34, 36 in the unitary reference electrode assembly 26 remain within their respective individual boundaries, without dispersing into neighboring layers. Therefore, for example, the LFP layer 34 in the reference electrode assembly 26 is characterized by an absence therein of dispersed carbon.

With resumed reference to FIG. 1, monitoring of the positive and negative electrode potentials of the Li-Ion cell 10 using the reference electrode assembly 26 may be performed via two individual measurement devices, such as a first voltage meter M1 and a second voltage meter M2. The first voltage meter M1 may be electrically connected to the negative and positive electrodes 14, 16 via the negative and positive electrode current collectors 22, 24 to detect a potential between the subject negative and positive electrodes. The second voltage meter M2 may be electrically connected to the negative electrode 22 and the reference electrode assembly 26 via the negative and reference electrode current collectors 22, 30 to detect a potential difference between the subject negative electrode and the reference electrode. Because characteristics of the reference electrode 30 are known, the measurement by the second voltage meter M2 facilitates the determination of individual potential of the negative electrode 14. Therefore, individual potential of the positive electrode 16 may be determined from the above measurements.

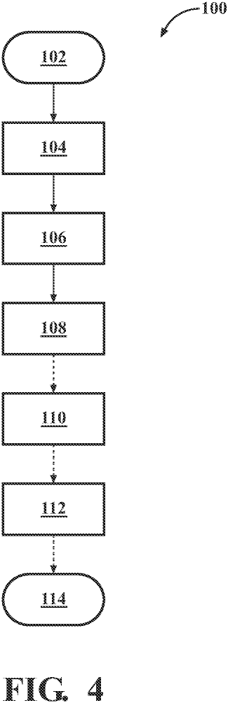

A method 100 of fabricating the reference electrode assembly 26 for an electrochemical cell, such as the Li-Ion cell 10 described with respect to FIGS. 1-3, is depicted in FIG. 4 and disclosed in detail below. Method 100 may commence in frame 102 with either doping or coating the separator 28 constructed from an electrically-insulating porous material with the ceramic material 28A, as described above with respect to FIGS. 2-3, and then advance to frame 104. Alternatively, method 100 may commence in frame 104 with setting up the separator 28 in the vacuum chamber 200. Setting up the separator 28 in the vacuum chamber 200 may include arranging the separator on a movable fixture 202 configured to be transported, such as on rolls 204, inside and with respect to the vacuum chamber 200 (shown in FIG. 5) during deposition of the constituent layers of the reference electrode assembly 26 as described in the following steps. Alternatively, setting up the separator 28 in the vacuum chamber 200 may include arranging the separator on a stationary fixture 206 (shown in FIG. 6).

After frame 104, the method advances to apply the current collector 30 onto the separator 28, starting in frame 106. In frame 106, the method includes, sputtering, in the vacuum chamber 200, the electrically-conducting porous layer 32 directly onto or over the separator 28. As described with respect to FIGS. 1-3 above, the sputtered electrically-conducting porous layer 32 may include the aluminum layer 32A having a thickness in the 50-500 nm range and may also have the carbon layer 32B with a thickness in the 5 -50 nm range. Alternatively, the sputtered electrically-conducting porous layer 32 may include the graphite-carbon layer having a thickness in the 50-500 nm range, the nickel layer with thickness in the 50-500 nm range, or the Tin layer with thickness in the 50-500 nm range.

After frame 106, the method advances to frame 108. In frame 108 the method includes sputtering, in the vacuum chamber 200, the lithium iron phosphate (LFP) layer 34 directly onto the sputtered electrically-conducting porous layer 32. The sputtered LFP layer 34 may have a thickness in the 70-500 nm range. As shown in FIG. 5, stationary current collector target 208 may be arranged in position P1A, while the stationary LFP target 210 may be arranged in position P2A. Applying the current collector 30 onto the reference electrode separator 28 may include bombarding a stationary current collector target 208 across from the positioned movable fixture 202, and thereafter shifting the movable fixture 202 to locate the fixture across from the stationary LFP target 210 and bombarding the LFP target. Thus, transporting the movable fixture 202 and sequentially bombarding the stationary current collector target 208 and LFP target 210 in their respective positions P1A and P2A, vacuum deposits the respective electrically-conducting porous layer 32 and the LFP layer 34 onto or over the reference electrode separator 28.

Alternatively, as shown in FIG. 6, the method may include setting up the current collector target 208 and the LFP target 210 on a movable fixture 212, such as a rotatable turret, for applying the current collector 30 onto the reference electrode separator 28. The movable fixture 212 may specifically include individual indexed positions P1B and P2B for the respective current collector target 208 and the LFP target 210 (shown in FIG. 6). Applying the current collector 30 onto the reference electrode separator 28 may include shifting the movable fixture 212 from position P1B to position P2B to first align the current collector target 208 and then the LFP target 210 with the reference electrode separator 28. Shifting the movable fixture 212 from position P1B to position P2B permits sequentially bombarding the respective current collector target 208 and the LFP target 210 to vacuum deposit the respective electrically-conducting porous layer 32 and the LFP layer 34 onto the reference electrode separator 28.

From frame 108, method 100 may advance to frame 110, where the method includes generating the electrical contact 36 connected to the current collector 30. The electrical contact 36 may be fabricated by applying the epoxy tab 36A from either gold/graphite or silver to an extension of or a projection from the current collector 30. After frame 110, the method may proceed to frame 112. In frame 112 the method may include organizing, packaging, and/or queueing up the reference electrode assembly 26 for subsequent incorporation into an electrochemical cell, such as the Li-Ion cell 10 described above. The method may conclude in frame 114.

The detailed description and the drawings or figures are supportive and descriptive of the disclosure, but the scope of the disclosure is defined solely by the claims. While some of the best modes and other embodiments for carrying out the claimed disclosure have been described in detail, various alternative designs and embodiments exist for practicing the disclosure defined in the appended claims. Furthermore, the embodiments shown in the drawings or the characteristics of various embodiments mentioned in the present description are not necessarily to be understood as embodiments independent of each other. Rather, it is possible that each of the characteristics described in one of the examples of an embodiment may be combined with one or a plurality of other desired characteristics from other embodiments, resulting in other embodiments not described in words or by reference to the drawings. Accordingly, such other embodiments fall within the framework of the scope of the appended claims.

What is claimed is:

1. A reference electrode assembly for an electrochemical cell, the reference electrode assembly comprising:
a separator constructed from an electrically-insulating porous material;
a current collector including:
a sputtered electrically-conducting porous layer arranged directly on the separator; and
a sputtered lithium iron phosphate (LFP) layer arranged directly on the electrically-conducting porous layer; and
an electrical contact connected to the current collector.

2. The reference electrode assembly of claim 1, wherein the electrical contact includes one of a gold/graphite and a silver epoxy tab.

3. The reference electrode assembly of claim 1, wherein the separator is one of doped and coated with a ceramic material.

4. The reference electrode assembly of claim 1, wherein the electrically-conducting porous layer includes an aluminum layer having a thickness in a 50-500 nm range and arranged directly on the separator.

5. The reference electrode assembly of claim 4, wherein the electrically-conducting porous layer additionally includes a carbon layer having a thickness in a 5-50 nm range arranged directly on the aluminum layer, such that the aluminum layer is sandwiched between the separator and the carbon layer.

6. The reference electrode assembly of claim 1, wherein the electrically-conducting porous layer includes a graphite-carbon layer having a thickness in a 50-500 nm range and arranged directly on the separator.

7. The reference electrode assembly of claim 1, wherein the electrically-conducting porous layer includes a nickel (Ni) layer having a thickness in a 50-500 nm range and arranged directly on the separator.

8. The reference electrode assembly of claim 1, wherein the electrically-conducting porous layer includes a Tin (Sn) having a thickness in a 50-500 nm range and arranged directly on the separator.

9. The reference electrode assembly of claim 1, wherein the LFP layer has a thickness in a 70-500 nm range.

10. A method of fabricating a reference electrode assembly for an electrochemical cell, the method comprising:
setting up in a vacuum chamber a separator constructed from an electrically-insulating porous material; and
applying a current collector onto the separator, including:
sputtering, in the vacuum chamber, directly onto the separator an electrically-conducting porous layer; and
sputtering, in the vacuum chamber, directly onto the sputtered electrically-conducting porous layer a lithium iron phosphate (LFP) layer.

11. The method of claim 9, further comprising generating an electrical contact connected to the current collector via applying an epoxy tab from one of gold/graphite and silver.

12. The method of claim 10, wherein prior to setting up the separator in the vacuum chamber, the method includes one of doping and coating the separator with a ceramic material.

13. The method of claim 10, wherein sputtering the electrically-conducting porous layer includes sputtering an aluminum layer having a thickness in a 50-500 nm range directly onto the separator.

14. The method of claim 13, wherein sputtering the electrically-conducting porous layer additionally includes sputtering a carbon layer having a thickness in a 5-50 nm range directly onto the aluminum layer, such that the aluminum layer is sandwiched between the separator and the carbon layer.

15. The method of claim 10, wherein sputtering the electrically-conducting porous layer includes sputtering a graphite-carbon layer having a thickness in a 50-500 nm range directly onto the separator.

16. The method of claim 10, wherein sputtering the electrically-conducting porous layer includes sputtering a nickel (Ni) layer having a thickness in a 50-500 nm range directly onto the separator.

17. The method of claim 10, wherein sputtering the electrically-conducting porous layer includes sputtering a Tin (Sn) having a thickness in a 50-500 nm range directly onto the separator.

18. The method of claim 10, wherein:
setting up in the vacuum chamber the separator includes arranging the separator on a movable fixture; and
applying the current collector onto the separator includes bombarding a stationary current collector target and a stationary LFP target to vacuum deposit the respective electrically-conducting porous layer and the LFP layer onto the separator while transporting the movable fixture.

19. The method of claim 10, wherein:
setting up in the vacuum chamber the separator includes arranging the separator on a stationary fixture; and
applying the current collector onto the separator includes setting up a current collector target and an LFP target on a movable fixture and sequentially bombarding the respective current collector target and the LFP target while shifting the movable fixture to vacuum deposit the respective electrically-conducting porous layer and the LFP layer onto the separator.

20. The method of claim 10, wherein sputtering the LFP layer includes vacuum depositing the LFP layer having a thickness in a 70-500 nm range.
